(19) United States
(12) Patent Application Publication
(10) Pub. No.: US 2007/0198205 A1
(43) Pub. Date: Aug. 23, 2007

(54) TEST APPARATUS

(75) Inventor: MICHIO SHIMURA, TOKYO (JP)

Correspondence Address: J C PATENTS, INC., 4 VENTURE, SUITE 250, IRVINE, CA, 92618, US

(73) Assignee: ADVANTEST CORPORATION, TOKYO (JP)

(21) Appl. No.: 11/681,071

(22) Filed: Mar. 1, 2007

Related U.S. Application Data
(63) Continuation-in-part of application No. PCT/JP05/22313, filed on Dec. 5, 2005.

(30) Foreign Application Priority Data
Dec. 7, 2004 (JP) 2004-354482

(51) Int. Cl. G01R 27/28

(52) U.S. Cl. 702/118; 702/108; 702/117; 702/124

(57) ABSTRACT

A test apparatus that tests a plurality of electronic devices in parallel is provided. The test apparatus includes: a pattern generating section that generates a test pattern provided to the plurality of electronic devices; a plurality of logical comparator circuits arranged corresponding to the plurality of electronic devices that judges Pass/Fail of an output signal for each pin based on the output signal outputted from each pin for the corresponding electronic device and serially outputs fail information for each pin; a serial reading section that serially reads out for each pin the fail information judged by each of the logical comparator circuit; an OR section that calculates for each of the electronic devices the logical sum of the fail information read out by the serial reading section and generates for each of the electronic devices device fail information indicative of Fail when the fail information for any pin indicates Fail; and an AND section that calculates the logical product of the device fail information generated by the OR section and generates total fail information indicative of Fail when all of the device fail information indicates Fail.

### CROSS REFERENCE TO RELATED APPLICATION

This is a continuation in-part application of PCT/JP2005/022313 filed on Dec. 5, 2005 which claims priority from a Japanese Patent Application NO. 2004-354482 filed on Dec. 7, 2004, the contents of which are incorporated herein by reference.

### BACKGROUND

1. Field of the Invention

The present invention relates to a test apparatus that tests an electronic device. Particularly, the present invention relates to a test apparatus that tests a plurality of electronic devices in parallel.

2. Related Art

Generally, a test apparatus that tests a plurality of electronic devices such as semiconductor circuits in parallel has been known.

Judging that all electronic devices under testing at the same time are fail, such test apparatus stops testing the electronic devices because it is not necessary to continue to test them.

FIG. 8 is an example of configuration of a conventional test apparatus 300. The test apparatus 300 includes a tester control section 210, a pattern generating section 212, a plurality of logical comparator circuits (214-1-214-n, hereinafter generically referred to as 214) which are arranged corresponding to a plurality of electronic devices (DUT200-1-DUT200-n, hereinafter generically referred to as 200) and a fail detecting section 220.

The tester control section 210 causes the pattern generating section 212 to generate a predetermined test pattern and provide the same to each of the electronic devices 200. Each of the logical comparator circuits 214 receives an output signal outputted from each pin for the corresponding electronic device 200, detects Pass/Fail of the output signal and outputs Fail information indicating that the output signal from each pin is pass or fail. Here, if Fail of the output signal is detected, from then on, Fail will be outputted for the pin from which Fail of the output signal is detected. In addition, the logical comparator circuits 214 output fail information for each pin in parallel.

The fail detecting section 220 includes a plurality of OR sections (226-1-226-n, hereinafter generically referred to as 226) corresponding to the plurality of logical comparator circuits 214 and an AND section 228. Each of the OR circuits 226 calculates the logical sum of the fail information for each of the pins which is outputted from the corresponding logical comparator circuit 214 and outputs the same as device fail information. The AND section 228 calculates the logical product of the device fail information outputted from each of the OR section 226 and outputs the same as total fail information.

Thus, the total fail information is generated, which indicates Fail when Fail is detected for all the electronic devices 200. Then, when the Fail is detected as the total fail information, the pattern generating section 212 stops generating any test pattern and stops testing.

However, since the conventional test apparatus 300 detects total fail information in real time, the load of the hardware is increased as increasing the operating frequency of the electronic device 200. For example, the OR section 226 has to transmit the fail information for all the pins of the corresponding electronic device 200 at substantially the same time. However, such as measurable transmission skew is generated as increasing the operating frequency of the electric device 200, so that a problem such as an error detecting may be occurred. Such problem is more markedly appeared when the number of electronic devices 200 to be tested at the same time are increased, so that it is difficult to improve the efficiency of testing.

### SUMMARY

Thus, the object of the present invention is to provide a test apparatus which is capable of solving the problem accompanying the conventional art. The above and other objects can be achieved by combining the features recited in independent claims. Then, dependent claims define further effective specific example of the present invention.

In order to solve the above described problems, a first aspect of the present invention provides a test apparatus that tests a plurality of electronic devices in parallel. The test apparatus includes: a pattern generating section that generates a test pattern provided to the plurality of electronic devices; a plurality of logical comparator circuits arranged corresponding to the plurality of electronic devices that judge Pass/Fail of an output signal for each pin based on the output signal outputted from each pin for the corresponding electronic device and serially output fail information for each pin; and an OR section that calculates for each of the electronic devices the logical sum of the fail information for each pin and generates device fail information indicative of Fail when the fail information for any pin indicates Fail.

A second aspect of the present invention provides a test apparatus that tests a plurality of electronic devices in parallel. The test apparatus includes: a plurality of pin electronics boards each of which is corresponding to one or more electronic devices different from each other and transmits/receives signals to/from the corresponding electronic devices; a pattern generating section that generates a test pattern provided to the plurality of electronic devices through the pin electronics boards; a plurality of logical comparator circuits arranged corresponding to the plurality of pin electronics boards that judge Pass/Fail of an output signal for each pin based on the output signal outputted from each pin of the electronic device connected to the corresponding electronics board and serially output the fail information for each pin; and an OR section that calculates for each of the pin electronics boards the logical sum of the fail information for each pin and generates device fail information indicative of Fail when the fail information for any pin indicates Fail.

Here, all necessary features of the present invention are not listed in the summary of the invention. The sub-combinations of the features may become the invention.

### BRIEF DESCRIPTION OF THE DRAWINGS

FIG. 1 shows an example of configuration of a test apparatus 100 according to an embodiment of the present invention;

FIG. 2 shows an example of operation of the test apparatus 100 shown in FIG. 1;

FIG. 3 shows an example of data processing in a fail detecting section 20;

FIG. 4 shows another example of configuration of the fail detecting section 20;

FIG. 5 is a flowchart showing an example of operation of the test apparatus 100 using the fail detecting section 20 shown in FIG. 4;

FIG. 6 shows another example of configuration of the test apparatus 100;

FIG. 7 shows an example of configuration of a serial reading section 22; and

FIG. 8 shows a configuration of a conventional test apparatus 300.

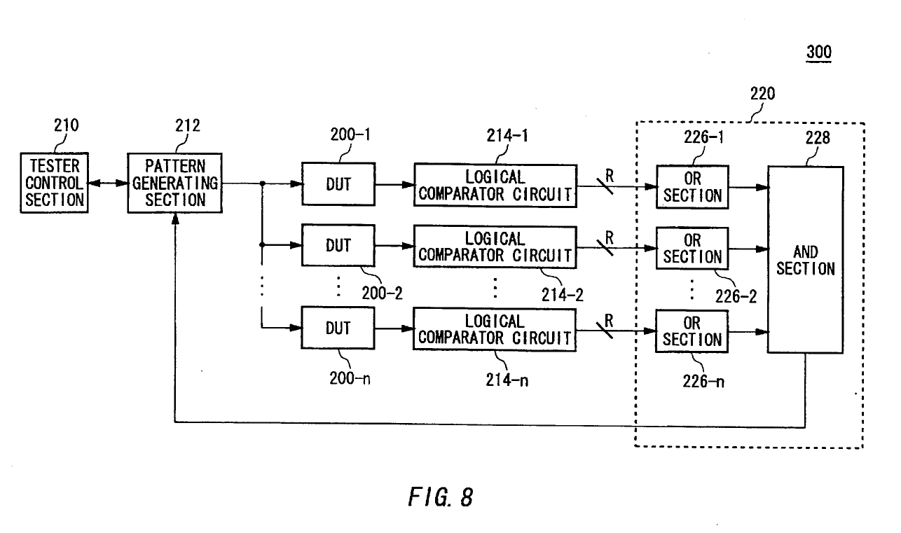

### DESCRIPTION OF EXEMPLARY EMBODIMENTS

Hereinafter, the present invention will now be described through preferred embodiments. The embodiments do not limit the invention according to claims and all combinations of the features described in the embodiments are not necessarily essential to means for solving the problems of the invention.

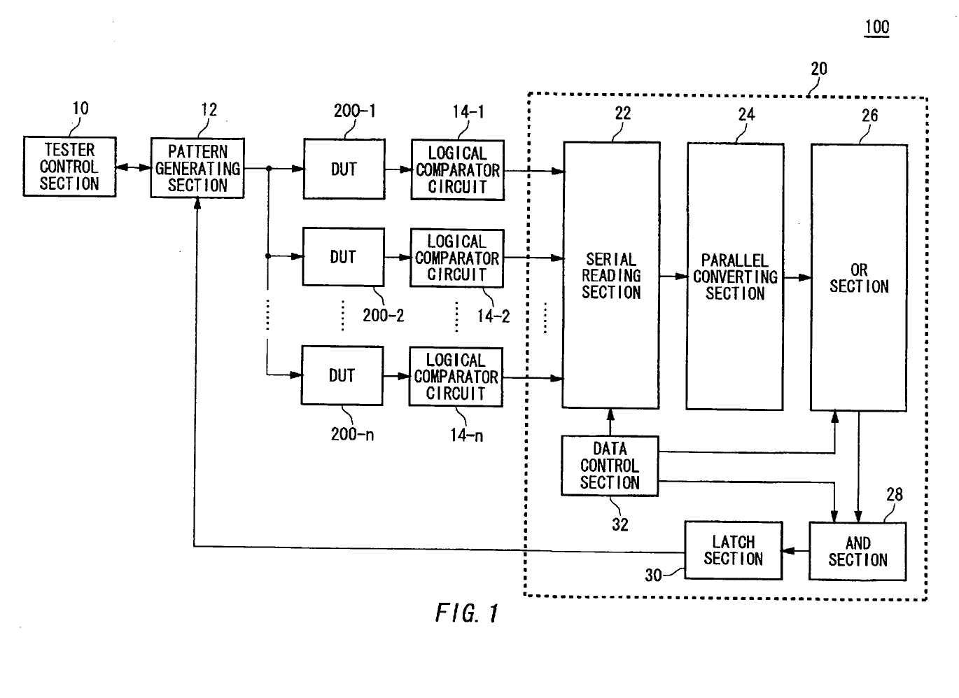

FIG. 1 shows an example of configuration of a test apparatus 100 according to an embodiment of the present invention. The test apparatus 100 tests a plurality of electronic devices 200 in parallel and includes a tester control section 10, a pattern generating section 12, a plurality of logical comparator circuits (14-1-14-n, hereinafter generically referred to as 14) and a fail detecting section 20.

The pattern generating section 12 generates a test pattern provided to the plurality of electronic devices 200. The tester control section 10 is previously provided with a test program and controls the pattern generating section 12 according to the test program to generate a predetermined test pattern.

The plurality of logical comparator circuits 14 are arranged corresponding to the plurality of electronic devices and receive an output signal outputted from each pin for each of the corresponding electronic devices 200. Each of the logical comparator circuits 14 judges for each pin Pass/Fail of the received output signal and generates fail information for each pin. Here, Pass/Fail of the output signal means that the output signal is corresponding to an expected value or not, for example. The fail information indicates Pass when the output signal is corresponding to the expected value and indicates Fail when the output signal is not corresponding to the expected value. Detecting Fail of the output signal, from then on, the logical comparator circuit 14 will output Fail as the fail information for the pin from which the fail is detected. Moreover, the logical comparator circuit 14 serially outputs fail information for each pin.

The fail detecting section 20 includes a serial reading section 22, a parallel converting section 24, an OR section 26, an AND section 28, a latch section 30 and a data control section 32. The serial reading section 22 reads out for each pin the fail information judged by each of the logical comparator circuits 14. The serial reading section 22 includes a storage means having a capacity being capable of storing fail information for all the pins of the plurality of electronic devices and serially reads the fail information for each of the logical comparator circuits in the present embodiment. That is, firstly the serial reading section 22 reads serially the fail information for each pin outputted by the logical comparator 14-1 and stores therein the same. Then, the serial reading section 22 serially reads out the fail information for each pin outputted by the logical comparator circuit 14-2 and stores therein the same after reading the fail information for all the pins outputted by the logical comparator circuit 14-1. The serial reading section 22 reads out the fail information outputted by all the logical comparator circuits 14 and stores therein the same by repeating such operation.

The parallel converting section 24 converts all the fail information read by the serial reading section 22 to parallel data. For example, when the serial reading section 22 serially stores the fail information in a shift register, the parallel converting section 24 outputs in parallel data stored in the shift register.

The OR section 26 calculates for each electric device 200 calculates the logical sum of the fail information read by the serial reading section 22 and generates for each electric device 200 device fail information indicative of Fail when the fail information for any pin indicates Fail. The OR section 26 according to the present embodiment receives the parallel data outputted by the parallel converting section 24 and calculates the logical sum of the fail information for data area of the parallel data, which is corresponding to each electronic device 200.

The data control section 32 generates device size information indicative of the data region of the parallel data, which is corresponding to each electronic device 200. The data control section 32 may be previously provided with the device size information by the user. The OR section 26 calculates the logical sum of the fail information for each data region indicated by the device size information.

The AND section 28 calculates the logical product of all the device fail information generated by the OR section 26 and generates total fail information indicative of Fail when all the device fail information indicate Fail. The latch section 30 holds the total fail information generated by the AND section 28 and provides the same to the tester control section 10 through the pattern generating section 12.

After the parallel converting section 24 outputs the parallel data to the OR section 26, the data control section 32 causes the serial reading section 22 to read new fail information. The data control section 32 causes the parallel converting section 24, the OR section 26 and the AND section 28 to repeat the same operation.

When the total fail information held by the latch section 30 indicates Fail, the tester control section 10 causes the pattern generating section 12 to stop operating so that the test is stopped. By such operation, the test apparatus 100 can stop testing when Fail is detected for all the electronic devices 200 and efficiently perform tests. Moreover, the test apparatus 100 according to the present embodiment serially reads the fail information for each pin outputted by the logical comparator circuit 14-1, serially captures therein the same and then, performs logical operation. Therefore, it is not necessary to read the fail information in synchronism with the operation of the pattern generating section 12 and the logical comparator circuit 14, so that the load of the hardware can be reduced and the operation can be accurately performed even if the electronic device 200 operates at high speed. Moreover, the fail information is serially read out for each logical comparator circuit 14 and the logical operation is performed after the fail information for all the logical comparator circuits 14 are captured. Therefore, it is enough to perform a reading sequence and a logical operation sequence one time for the fail information, respectively, so that the detection sequence of the total fail can be easily generated.

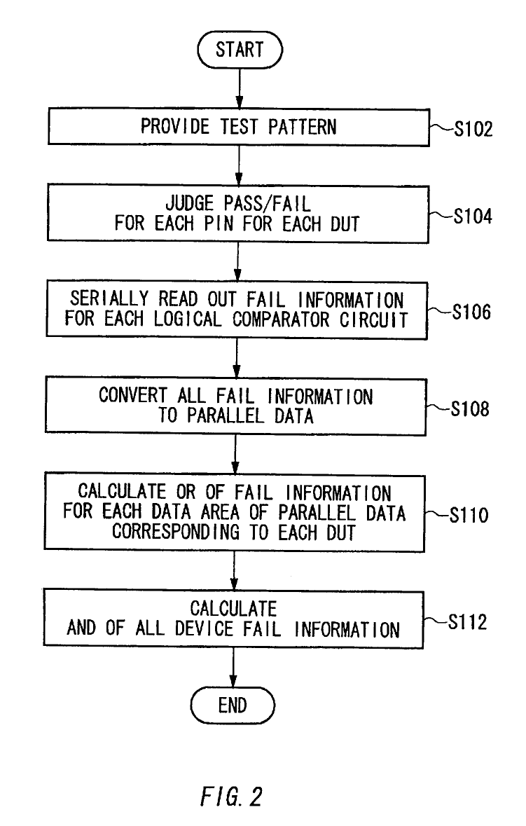

FIG. 2 is a flowchart showing an example of operation of the test apparatus shown in FIG. 1. As described above, the test apparatus 100 provides a test pattern to each of the electronic devices 200 (S102). Then, the test apparatus 100 judges Pass/Fail for each of the electronic devices 200. (S104).

Next, serial fail information is sequentially read out for each of the logical comparator circuits 14 and stored (S106). Then, all the fail information stored is converted to parallel data (S108). Then, the logical sum of the fail information is calculated for each data area of the parallel data, which is corresponding to each electronic device 200 and device fail information for each of the electronic devices 200 is generated. Then, the logical product of all the device fail information is calculated and the total fail information is generated (S112). The test apparatus 100 continues to test until the total fail information indicates Fail or all the test programs are performed.

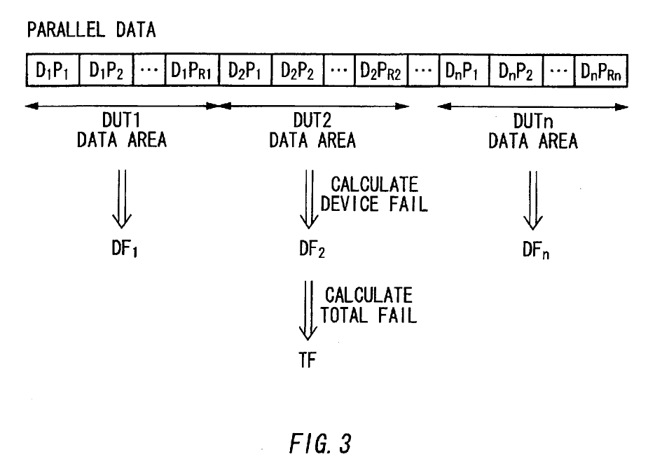

FIG. 3 shows an example of data processing in the fail detecting section 20. As shown in FIG. 3, the parallel converting section 24 converts the fail information for all the logical comparator circuits 14 read by the serial reading section 22 to parallel data. Data DₐP_{b} indicates fail information for b-th pin of the electronic device 200-a in FIG. 3. The data control section 32 generates device size information indicative of a data area of the parallel data, which is corresponding to each electronic device 200. For example, data control section 32 may create a start address and an end address in the data area corresponding to each electronic device 200.

Then, the OR section 26 calculates the logical sum of all the fail information included in the data area corresponding to each electronic device 200 based on the device size information provided from the data control section 32 and calculates each device fail information DF_{c} (here, C is any integer 1-n). Then, the AND section 28 calculates the logical product for all the device fail information DF_{c} and generates total fail information TF.

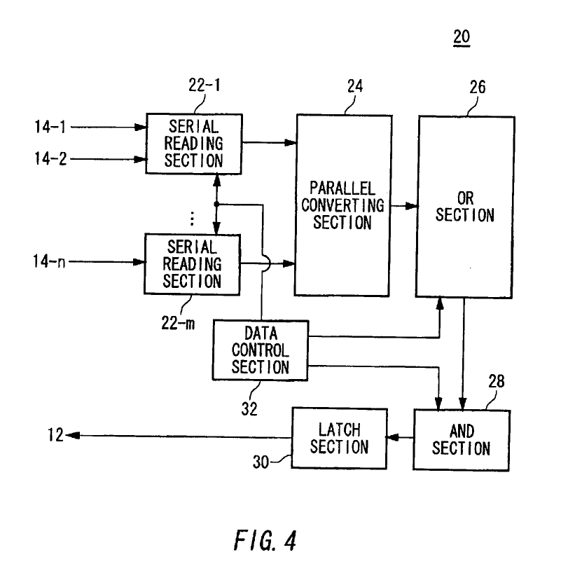

FIG. 4 shows another example of configuration of the fail detecting section 20. The fail detecting section 20 according to the present embodiment has a configuration the same as that of the fail detecting section 20 described with reference to FIG. 1 except for having a plurality of serial reading sections (22-1-22-m, hereinafter generically referred to as 22).

The plurality of serial reading sections are arranged in parallel. In this case, each of the logical comparator circuits 14 is provided corresponding to any of the serial reading sections 22. The logical comparator circuit 14-1 and the logical comparator circuit 14-2 are corresponding to the serial reading section 22-1, and the logical comparator circuit 14-n is corresponding to the serial reading section 22-m in the present embodiment.

Each of the serial reading sections 22 serially reads the fail information for each corresponding logical comparator circuit 14 and stores therein the same. The operation of each serial reading section 22 is the same as that of the serial reading section 22 described with reference to FIG. I except for reading only the fail information for the corresponding logical comparator circuit 14.

In this case, the parallel converting section 24 converts all the fail information stored in each of the serial reading sections 22 to parallel data. The parallel data is the same as that described with reference to FIG. 3.

Then, the OR section 26, the AND section 28 and the data control section 32 generate the total fail information from the parallel data, and the latch section 30 holds the total fail information and provides the same to the pattern generating section 12 as described with reference to FIG. 1-FIG. 3.

The test apparatus 100 according to the present embodiment can read in parallel the fail information outputted by the plurality of logical comparator circuits 14, so that the total fail information can be more speedily generated.

In addition, when the capacity of means for storing the fail information of the serial reading section 22 is not enough so that all the fail information serially outputted by the corresponding logical comparator circuits 14 can not stored, the overflowing fail information may be stored in the other serial reading section 22 provided adjacent thereto.

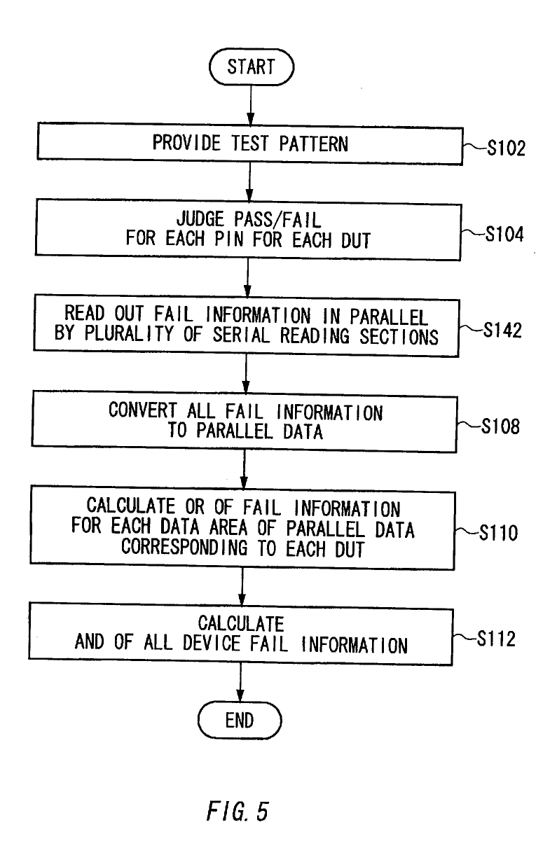

FIG. 5 shows an example of operation of test apparatus 100 using the fail detecting section 20 shown in FIG. 4.

The operation of the test apparatus 100 according to the present embodiment is the same as that of the test apparatus 100 shown in FIG. 2 except for performing a step S112 instead of the step S106.

As described above, the test apparatus 100 judges Pass/Fail for each pin for each of the electronic devices 200 by the logical comparator circuit 14 (S104), and then, the test apparatus 100 reads fail information in parallel by using the plurality of serial reading sections 22. Thereby the total fail information can be more speedily generated in comparison with the operation shown in FIG. 2.

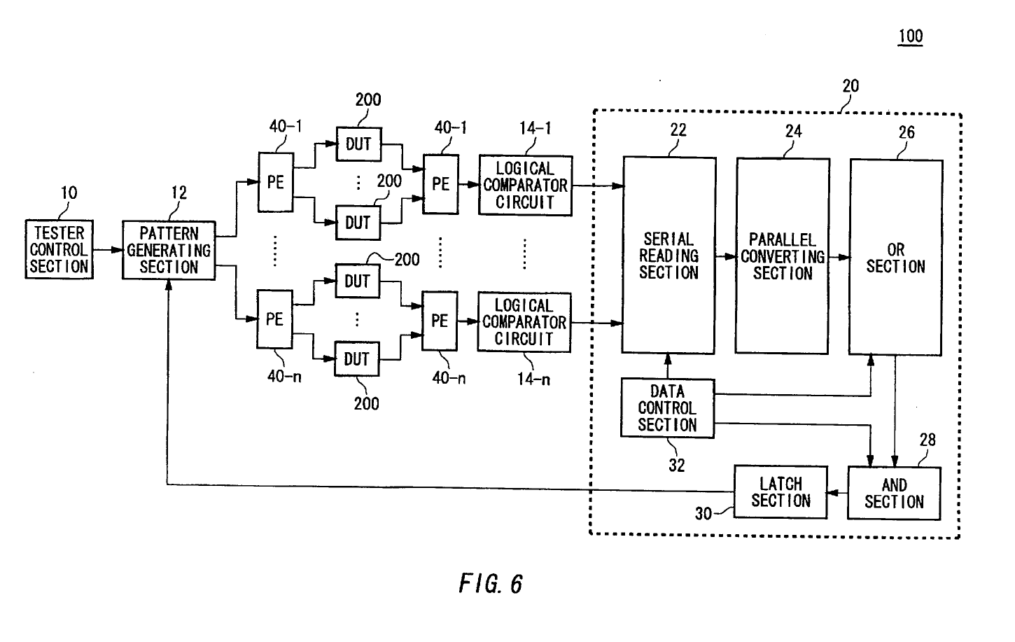

FIG. 6 shows another example of configuration of the test apparatus 100. The test apparatus 100 according to the present embodiment further includes a plurality of pin electronics boards (40-1-40-n, hereinafter generically referred to as 40) in addition to the components of the test apparatus 100 described with reference to FIG. 1. As for the rest, the test apparatus 100 has the functions and the configurations the same as those of the components having the reference numerals the same as those shown in FIG. 1.

Each of the pin electronics boards 40 is arranged corresponding to one or more electronic device(s) 200 and transmits/receives signals to/from the corresponding electronic device(s). For example, the pin electronics board 40 has the number of driver(s) and comparator(s) corresponding to the number of corresponding electronic device(s). The driver(s) and the comparator(s) may be arranged on one pin electronics board 40, and also may be arranged on the pin electronics boards 40 different from each other.

The driver inputs the signal corresponding to the test pattern outputted by the pattern generating section 12 to the electronic device 200. The driver is arranged on the pin electronics board 40 between the pattern generating section 12 and the electronic device 200 in the present embodiment.

The comparator inputs the signal outputted by the electronic device 200 to the logical comparator circuit 14-1. The comparator is arranged on the pin electronics board 40 between the electronic device 200 and the logical comparator circuit 14.

The plurality of logical comparator circuits 14 are arranged corresponding to the plurality of electronics boards 40. Each of the logical comparator circuits 14 receives the output signal from each pin of one or more of electronic devices 200 connected to the corresponding electronics board 40. Additionally, each of the logical comparator circuits 14 judges Pass/Fail of the received output signal for each pin and generates fail information for each pin. Moreover, each of the logical comparator circuit 14 serially outputs the fail information for each pin.

The OR section 26 calculates the logical sum of the fail information read by the serial reading section 22 for each of the pin electronics boards 40 and generates board fail information indicative of Fail when the fail information for any pin indicates Fail. The OR section 26 according to the present embodiment receives parallel data outputted by the parallel converting section 24 and calculates the logical sum of the fail information for each data area of the parallel data, which is corresponding to each of the pin electronics boards 40.

The data control section 32 generates board size information indicative of the data area of the parallel data, which is corresponding to each of the pin electronics boards 40. The board size information may be previously provided to the data control section 32 by the user. The OR section 26 calculates the logical sum of the fail information for each data area indicated by the board size information.

The AND section 28 calculates the logical product of all the board fail information generated by the OR section 26 and generates total fail information indicative of Fail when all the board fail information indicates Fail. The latch section 30 holds the total fail information generated by the AND section 28 and provides the same to the tester control section 10 through the pattern generating section 12.

In addition, the data control section 32 causes the serial reading section 22 to read new fail information after the parallel converting section 24 outputs the parallel data to the OR section 26. Then, the data control section 32 causes the parallel converting section 24, the OR section 26 and the AND section 28 to repeat the same operation.

When the total fail information held by the latch section 30 indicates Fail, the tester control section 10 stops the operation of the pattern generating section 12 to stop the testing. By such operation, the test can be stopped when Fail for all the pin electronics boards 40 are detected, so that the test can be efficiently performed.

As described above, the test apparatus 100 detects Fail for each electronic device 200 or each pin electronics board 40 so as to efficiently test. That is, when Fail is detected for each pin electronics board 40, the Fail is detected based on the plurality of electronic devices 200 connected to each pin electronics board 40 as a device unit, so that the test can be efficiently performed.

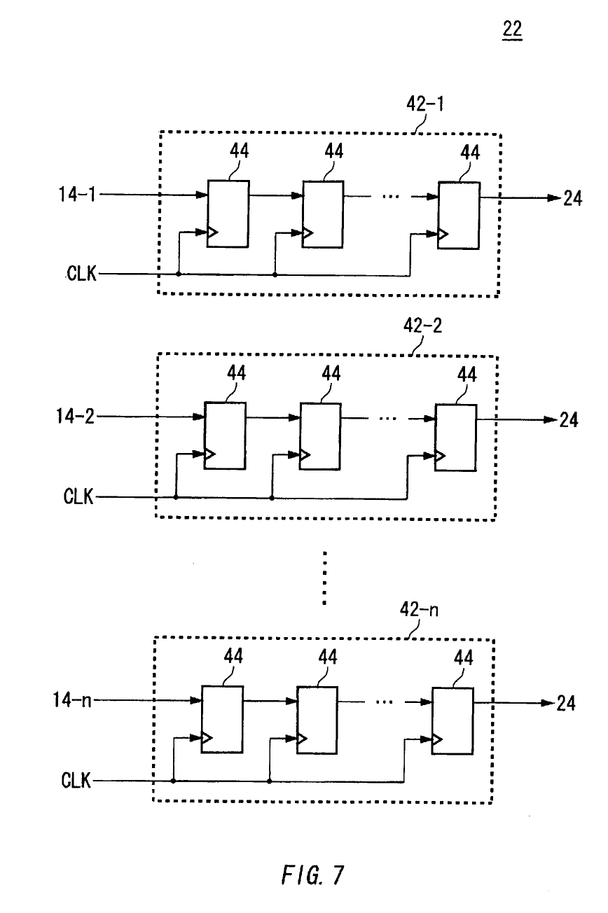

FIG. 7 shows an example of configuration of the serial reading section 22. The serial reading section 22 has the number of shift registers (42-1-42-n, hereinafter generically referred to as 42) corresponding to the number of the logical comparator circuits connected thereto.

Each of the shift register 42 has a plurality of registers 44 connected in series and captures data outputted by the corresponding logical comparator circuit 14 in synchronism with a clock (CLK) provided thereto. In addition, the shift register 42 serially outputs the captured data in synchronism with the CLK provided thereto.

While the present invention has been described with the embodiment, the technical scope of the invention not limited to the above described embodiment. It is apparent to persons skilled in the art that various alternations and improvements can be added to the above-described embodiment. It is apparent from the scope of the claims that the embodiment added such alternation or improvements can be included in the technical scope of the invention.

As evidenced by the above description, the test is stopped when Fail is detected for all the electronic devices, so that the test apparatus 10 can efficiently test. In addition, even if the electronic device operates at high speed, the load of the hardware can be reduced and the total fail information can be accurately generated.

What is claimed is:

1. A test apparatus that tests a plurality of electronic devices in parallel, comprising:
a pattern generating section that generates a test pattern provided to the plurality of electronic devices;
a plurality of logical comparator circuits arranged corresponding to the plurality of electronic devices that judge Pass/Fail of an output signal for each pin based on the output signal outputted from each pin for the corresponding electronic device and serially output fail information for each pin; and
an OR section that calculates for each of the electronic devices the logical sum of the fail information for each pin and generates device fail information indicative of Fail when the fail information for any pin indicates Fail.

2. The test apparatus as set forth in claim 1 further comprising a serial reading section that serially reads for each pin the fail information judged by each of the logical comparator circuits,
the OR section calculates for each electronic device the logical sum of the fail information read by the serial reading section and generates device fail information when the fail information for any pin indicates Fail.

3. The test apparatus as set forth in claim 2 further comprising an AND section that calculates the logical product of the device fail information generated by the OR section and generates total fail information indicative of Fail when all the device fail information indicate Fail.

4. The test apparatus as set forth in claim 3, wherein
the serial reading section includes a storage means having a capacity being capable of storing the fail information for all the pins of the plurality of electronic devices and serially reads the fail information for each logical comparator circuit.

5. The test apparatus as set forth in claim 3 further comprising a plurality of the serial reading sections arranged in parallel,
each of the logical comparator circuits is arranged corresponding to any of the serial reading sections, and
each of the serial reading sections serially reads the fail information for each corresponding logical comparator circuit and stores therein the same.

6. The test apparatus as set forth in claim 3, wherein
the OR section receives in parallel all the fail information stored in the serial reading sections,
the test apparatus further comprises a data control section that generates device size information indicative of a data area of the parallel data received by the OR section, which is corresponding to each of the electronic devices, and
the OR section calculates the logical sum of the fail information for each data area indicated by the device size information.

7. The test apparatus as set forth in claim 3 further comprising a tester control section that stops the operation of the pattern generating section when the total fail information indicates Fail.

8. A test apparatus that tests a plurality of electronic devices in parallel, comprising:
a plurality of pin electronics boards each of which is corresponding to one or more electronic devices different from each other and transmits/receives signals to/from the corresponding electronic devices;
a pattern generating section that generates a test pattern provided to the plurality of electronic devices through the pin electronics boards;
a plurality of logical comparator circuits arranged corresponding to the plurality of pin electronics boards that judge Pass/Fail of an output signal for each pin based on the output signal outputted from each pin of the electronic device connected to the corresponding electronics board and serially output the fail information for each pin; and
an OR section that calculates for each of the pin electronics boards the logical sum of the fail information for each pin and generates device fail information indicative of Fail when the fail information for any pin indicates Fail.

9. The test apparatus as set forth in claim 8 further comprising a serial reading section that serially reads for each pin the fail information judged by each of the logical comparator circuits;
the OR section calculates for each pin electronics board the logical sum of the fail information read by the serial reading section and generates for each of the pin electronics boards device fail information indicative of Fail when the fail information for any pin indicates Fail.

10. The test apparatus as set forth in claim 9 further comprising an AND section that calculates the logical product of the device fail information generated by the OR section and generates total fail information when all the device fail information indicate Fail.
